(19) United States
(12) Patent Application Publication
(10) Pub. No.: US 2025/0096214 A1
(43) Pub. Date: Mar. 20, 2025

(54) SEMICONDUCTOR PACKAGE AND METHOD FOR MANUFACTURING THE SAME

(71) Applicant: Samsung Electronics Co., Ltd., Suwon-si (KR)

(72) Inventors: HYUNSOO CHUNG, Suwon-si (KR); YOUNG LYONG KIM, Suwon-si (KR); CHI WOO LEE, Suwon-si (KR)

(21) Appl. No.: 18/626,691

(22) Filed: Apr. 4, 2024

(30) Foreign Application Priority Data
Sep. 18, 2023 (KR) 10-2023-0123884

(51) Int. Cl. H01L 25/16; H01L 21/48; H01L 21/56; H01L 23/00; H01L 23/31; H01L 23/498; H10B 80/00

(52) U.S. Cl. CPC H01L 25/167; H01L 21/4846; H01L 21/565; H01L 21/568; H01L 23/3135; H01L 23/49827; H01L 24/13; H01L 24/16; H10B 80/00; H01L 2224/13147; H01L 2224/16148; H01L 2224/16227; H01L 2924/1432; H01L 2924/1436

(57) ABSTRACT

An embodiment provides a semiconductor package including: a redistribution structure; an interconnection structure on the redistribution structure; a memory stacking structure disposed on the redistribution structure and including a buffer die and core dies stacked on the buffer die; a semiconductor die disposed on the buffer die and on the interconnection structure; and an optical engine disposed on the interconnection structure.

### CROSS-REFERENCE TO RELATED APPLICATION

This application claims priority to and the benefit of Korean Patent Application No. 10-2023-0123884 filed on Sep. 18, 2023 in the Korean Intellectual Property Office, the entire contents of which are herein incorporated by reference.

### BACKGROUND OF THE INVENTION

### (a) Field of the Invention

The present disclosure relates to a semiconductor package and a method for manufacturing the same.

### (b) Description of the Related Art

Demand for data used in individual electronic devices is increasing, and traffic between data centers and such individual electronic devices is expanding accordingly. In this case, co-packaged optics (CPO), which includes an optical engine such as an optical transceiver and an integrated circuit, has been developed as a device for processing high-bandwidth signals transmitted and received in data centers.

The CPO includes an optical engine used to receive optical signals and convert between optical and electrical signals, and semiconductor chips that process the converted electrical signals and control the optical engine. Currently, the optical engine and semiconductor chips in the CPO are packaged on an interposer and redistribution structure, and according to this packaged structure, since the distance between the optical engine and the semiconductor chips is long and the signal transmission process through the interposer and redistribution structure is not optimized, power loss occurs during the signal transmission process.

Therefore, it is necessary to develop a new package technology that may solve the aforesaid problems of the CPO.

### SUMMARY OF THE INVENTION

A buffer die and an interposer, which are components of a memory stacking structure, may be disposed on a redistribution structure, and a logic circuit may be disposed on the buffer die and the interposer.

A buffer die and a bridge die, which are components of a memory stacking structure, may be disposed on a redistribution structure, and a logic circuit may be disposed on the buffer die and the bridge die.

An embodiment provides a semiconductor package including: a redistribution structure; an interconnection structure on the redistribution structure; a memory stacking structure disposed on the redistribution structure and including a buffer die and core dies stacked on the buffer die; a semiconductor die disposed on the buffer die and on the interconnection structure; and an optical engine disposed on the interconnection structure.

An embodiment provides a semiconductor package including: a redistribution structure; an interconnection structure on the redistribution structure; a memory stacking structure disposed on the redistribution structure and including a buffer die and core dies stacked on the buffer die; a first molding material disposed on the redistribution structure and covering the interconnection structure and the buffer die; a semiconductor die disposed on the buffer die and on the interconnection structure; an optical engine disposed on the interconnection structure; and a second molding material disposed on the first molding material and covering the stacked core dies, the semiconductor die, and the optical engine.

An embodiment provides a manufacturing method of a semiconductor package, including: attaching a buffer die and an interconnection structure onto a carrier; molding the buffer die and the interconnection structure on the carrier with a first molding material; forming core dies stacked on the buffer die, mounting a semiconductor die on the buffer die and the interconnection structure, and mounting an optical engine on the interconnection structure; molding the stacked core dies, the semiconductor die, and the optical engine on the first molding material with a second molding material; removing the carrier to expose the buffer die and the interconnect structure; and forming a redistribution structure on the buffer die and the interconnect structure.

A buffer die and an interposer, which are components of a memory stacking structure, may be disposed on a redistribution structure, and a logic circuit may be disposed on the buffer die and the interposer.

A buffer die and a bridge die, which are components of a memory stacking structure, may be disposed on a redistribution structure, and a logic circuit may be disposed on the buffer die and the bridge die.

This packaging structure may improve power efficiency by reducing power loss occurring during signal transmission.

### BRIEF DESCRIPTION OF THE DRAWINGS

FIG. 1 illustrates a cross-sectional view of a semiconductor package according to an embodiment.

FIG. 2 to FIG. 5 illustrate cross-sectional views of a manufacturing method of an optical engine.

FIG. 6 to FIG. 16 illustrate cross-sectional views of a manufacturing method of the semiconductor package of FIG. 1.

FIG. 17 illustrates a cross-sectional view of a semiconductor package according to an embodiment.

FIG. 18 to FIG. 27 illustrate cross-sectional views of a manufacturing method of the semiconductor package of FIG. 17.

### DETAILED DESCRIPTION OF THE EMBODIMENTS

The present disclosure will be described more fully hereinafter with reference to the accompanying drawings, in which embodiments of the present disclosure are shown. As those skilled in the art would realize, the described embodiments may be modified in various different ways, all without departing from the spirit or scope of the present disclosure.

In order to clearly describe the present disclosure, parts that are irrelevant to the description are omitted, and identical or similar constituent elements throughout the specification are denoted by the same reference numerals.

Furthermore, in the drawings, the size and thickness of each element are arbitrarily illustrated for ease of description, and the present disclosure is not necessarily limited to those illustrated in the drawings.

Throughout this specification and the claims that follow, when it is described that an element is “coupled or connected” to another element, the element may be “directly coupled or connected” to the other element or “indirectly coupled or connected” to the other element through a third element. In addition, unless explicitly described to the contrary, the word “comprise” and variations such as “comprises” or “comprising” will be understood to imply the inclusion of stated elements but not the exclusion of any other elements.

It will be understood that when an element such as a layer, film, region, area, or substrate is referred to as being “on” or “above” another element, it can be directly on the other element or intervening elements may also be present. In contrast, when an element is referred to as being “directly on” another element, there are no intervening elements present. Further, in the specification, the word “on” or “above” means disposed on or below the object portion, and does not necessarily mean disposed on the upper side of the object portion based on a gravitational direction.

Furthermore, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

Hereinafter, a semiconductor package 100 and a manufacturing method of the semiconductor package 100 according to an embodiment will be described with reference to the accompanying drawings.

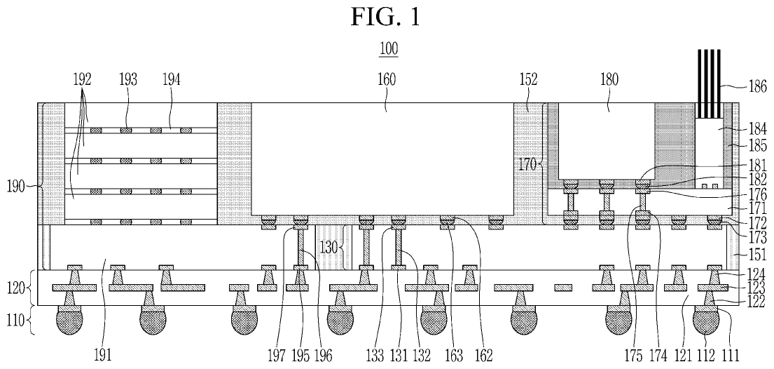

FIG. 1 illustrates a cross-sectional view of a semiconductor package 100 according to an embodiment.

Referring to FIG. 1, the semiconductor package 100 includes an external connection structure 110, a redistribution structure 120, an interconnection structure 130, a first molding material 151, a semiconductor die 160, an optical engine 170, memory stacking structures 190, and a second molding material 152. In the embodiment, the semiconductor package 100 may include a fan out wafer level package (FOWLP) or a fan out panel level package (FOPLP).

The external connection structure 110 is disposed on a lower surface of the redistribution structure 120. The external connection structure 110 may include conductive pads 111 and external connection members 112. The conductive pad 111 electrically connects a first redistribution via 122 of the redistribution structure 120 to the external connection member 112. The external connection member 112 electrically connects the semiconductor package 100 to an external device.

The redistribution structure 120 may include a dielectric layer 121, and first redistribution vias 122, first redistribution lines 123, and second redistribution vias 124 within the dielectric layer 121. In some embodiments, a redistribution structure 120 that include fewer or more numbers of redistribution lines and redistribution vias may be included within the scope of the present disclosure.

The dielectric layer 121 protects and insulates the first redistribution vias 122, the first redistribution lines 123, and the second redistribution vias 124. The interconnection structure 130, the memory stacking structure 190, and the first molding material 151 are disposed on an upper surface of the dielectric layer 121. The external connection structure 110 is disposed on a lower surface of the dielectric layer 121.

The first redistribution via 122 is disposed between the first redistribution line 123 and the conductive pad 111. The first redistribution via 122 electrically connects the first redistribution line 123 to the external connection member 112 connected to the conductive pad 111 in a vertical direction, which is perpendicular to an upper surface of the redistribution structure 120. The first redistribution line 123 is disposed between the first redistribution via 122 and the second redistribution via 124. The first redistribution line 123 electrically connects the first redistribution via 122 and the second redistribution via 124 in a horizontal direction, which is parallel to the upper surface of the redistribution structure 120. For example, the first redistribution line 123 extends in the horizontal direction, connecting the second redistribution via 124 to the first redistribution via 122 . . . . The second redistribution via 124 is disposed between a first lower connection pad 131 of the interconnection structure 130 and the first redistribution line 123, and between a buffer die 191 and a second lower connection pad 195. The second redistribution via 124 electrically connects the first lower connection pad 131 to the first redistribution line 123, and the second lower connection pad 195 to the first redistribution line 123, in the vertical direction.

The interconnection structure 130 electrically connects the semiconductor die 160 to the optical engine 170 in the horizontal direction, electrically connects the optical engine 170 to the redistribution structure 120 in the vertical direction, and electrically connects the semiconductor die 160 to the redistribution structure 120 in the vertical direction. The upper surface of the interconnection structure 130 has the same level as the upper surface of the buffer die 191.

The interconnection structure 130 includes first lower connection pads 131, first through silicon vias (TSV) 132, and first upper connection pads 133. In the embodiment, the interconnection structure 130 may include a silicon interposer. The side surface of the interconnection structure 130 is covered with the first molding material 151. For example, the first molding material 151 may surround the side surface of the interconnection structure 130. The first through silicon via (TSV) 132 included in the interconnection structure 130 rapidly moves data in the vertical direction. For example, the first through-hole silicon via (TSV) 132 included in the interconnection structure 130 may serve as a shorter vertical signal path for transferring data in the vertical direction. Accordingly, the signal transmission path between the semiconductor die 160 and the redistribution structure 120 may be optimized (i.e., reduced), thereby reducing power consumption to improve the performance of the semiconductor package.

The first lower connection pad 131 is disposed between the second redistribution via 124 of the redistribution structure 120 and the first through silicon via (TSV) 132 and on the second redistribution via 124, and electrically connects the first through silicon via (TSV) 132 to the second redistribution via 124 of the redistribution structure 120.

The first through silicon via (TSV) 132 is disposed between the first lower connection pad 131 and the first upper connection pad 133, and electrically connects the semiconductor die 160 connected to the first upper connection pad 133 in the vertical direction to the redistribution structure 120 connected to the first lower connection pad 131.

The first upper connection pad 133 is disposed between the first through silicon via (TSV) 132 and the first connection member 163, below the first connection member 163, and below the second connection member 173, and electrically connects the first connection member 163 to the first through silicon via (TSV) 132.

In the embodiment, the first through silicon via (TSV) 132 may include or may be formed of at least one of tungsten, aluminum, copper, and an alloy thereof. In the embodiment, each of the first lower connection pad 131 and the first upper connection pad 133 may include or may be formed of at least one of copper, aluminum, silver, tin, gold, nickel, lead, titanium, and an alloy thereof.

The memory stacking structure 190 is disposed on the redistribution structure 120. The memory stacking structure 190 includes a buffer die 191, stacked core dies 192, an interconnection member 193, and an insulation member 194. In the embodiment, the memory stacking structure 190 may include a high bandwidth memory (HBM). The upper surface of the memory stacking structure 190 has the same level as the upper surface of the semiconductor die 160 and the upper surface of the optical engine 170.

The buffer die 191 is disposed at the lowermost portion of the memory stacked structure 190. The buffer die 191 is disposed on the redistribution structure 120. The upper surface of the buffer die 191 has the same level as the upper surface of the interconnection structure 130. When data is exchanged between devices with different processing speeds, processing units, and usage times, data loss may occur due to differences in processing speed, processing unit, and usage time between respective devices. To prevent this data loss, the buffer die 191 is disposed between the stacked core dies 192 and the semiconductor die 160, and information when data is exchanged between the stacked core dies 192 and the semiconductor die 160 is temporarily stored in the buffer die 191. When transmitting data to the stacked core dies 192 or receiving data from the stacked core dies 192, the buffer die 191 sequentially passes the data after sequencing the data.

The buffer die 191 includes second lower connection pads 195, second through silicon vias (TSV) 196, and second upper connection pads 197. The side surface of the buffer die 191 is covered with the first molding material 151. The second through silicon via (TSV) 196 included in the buffer die 191 rapidly moves data in the vertical direction. For example, the second through silicon via (TSV) 196 included in the buffer die 191 may serve as a shorter vertical signal path for transferring data in the vertical direction. Accordingly, the signal transmission path between the semiconductor die 160 and the redistribution structure 120 may be optimized (i.e., reduced), thereby reducing power consumption to improve the performance of the semiconductor package.

The second lower connection pad 195 is disposed between the second redistribution via 124 of the redistribution structure 120 and the second through silicon via (TSV) 196 and on the second redistribution via 124, and electrically connects the second through silicon via (TSV) 196 to the second redistribution via 124 of the redistribution structure 120.

The second through silicon via (TSV) 196 is disposed between the second lower connection pad 195 and the second upper connection pad 197, and electrically connects the semiconductor die 160 connected to the second upper connection pad 197 in the vertical direction to the redistribution structure 120 connected to the second lower connection pad 195.

The second upper connection pad 197 is disposed between the second through silicon via (TSV) 196 and the first connection member 163, and below the first connection member 163, and electrically connects the first connection member 163 to the second through silicon via (TSV) 196.

In the embodiment, the second through silicon via (TSV) 196 may include or may be formed of at least one of tungsten, aluminum, copper, and an alloy thereof. Each of the second lower connection pad 195 and the second upper connection pad 197 may include or may be formed of at least one of copper, aluminum, silver, tin, gold, nickel, lead, titanium, and an alloy thereof.

The stacked core dies 192 are disposed on the buffer die 191. The stacked core dies 192 are surrounded by the second molding material 152. Each of the stacked core dies 192 includes memory channels and through silicon vias. In the embodiment, each of the core dies 192 may be dynamic random access memory (DRAM). In the embodiment, a high-bandwidth memory including fewer or more core dies 192 is included in the scope of the present disclosure.

The interconnection members 193 are disposed between the buffer die 191 and the stacked core dies 192, and between the stacked core dies 192. The interconnection member 193 electrically connects the stacked core dies 192 to the buffer die 191 and the stacked core dies 192 with each other. In the embodiment, the interconnection members 193 may include micro bumps. In the embodiment, the interconnection member 193 may include copper.

The insulation member 194 is disposed between the buffer die 191 and the stacked core dies 192 and between the stacked core dies 192 to surrounds the interconnection member 193. The insulation member 194 relieves stress between the buffer die 191 and the stacked core dies 192 and between the stacked core dies 192. In the embodiment, the insulation member 194 may include or may be a non-conductive film (NCF).

The first molding material 151 molds the interconnection structure 130 and the buffer die 191 on the redistribution structure 120. The first molding material 151 protects the interconnection structure 130 and the buffer die 191 from the external environment, and thus the semiconductor package 100 may secure electrical or mechanical stability.

The semiconductor die 160 is disposed on the interconnection structure 130 and the buffer die 191. The semiconductor die 160 is surrounded by the second molding material 152. The semiconductor die 160 includes first connection pads 162, and first connection members 163. In the embodiment, the semiconductor die 160 may include a logic die. In the embodiment, the semiconductor die 160 may include an XPU. The XPU is a processing unit that combines a system on chip (SoC), a central processing unit (CPU), a graphics processing unit (GPU), a field programmable gate array (FPGA), an application specific integrated circuit (ASIC), and an AI accelerator. The XPU includes the ability to select the appropriate processor for each task using software. In the embodiment, the semiconductor die 160 may include at least one of a central processing unit (CPU) and a graphics processing unit (GPU). The semiconductor die 160 is electrically connected to the interconnection structure 130 and the buffer die 191 through the first connection pads 162 and the first connection members 163.

The first connection pad 162 is disposed between a semiconductor die base and the first connection member 163. The first connection pad 162 electrically connects the semiconductor die base to the first connection member 163. The first connection member 163 is disposed between the first connection pad 162 and the first upper connection pad 133, and between the first connection pad 162 and the second upper connection pad 197. The first connection member 163 electrically connects the first connection pad 162 to the first upper connection pad 133, and the first connection pad 162 to the second upper connection pad 197. The buffer die 191 is directly connected to corresponding first connection members 163, and the interconnection structure 130 are directly connected to corresponding first connection members 163. In the embodiment, the first connection pad 162 may include or may be formed of at least one of copper, nickel, zinc, gold, silver, platinum, palladium, chromium, titanium, and an alloy thereof. In the embodiment, the first connection member 163 may be a micro bump. In the embodiment, the first connection member 163 may include or may be formed of at least one of tin, silver, lead, nickel, copper, and an alloy thereof.

The optical engine 170 is disposed on the interconnection structure 130. The optical engine 170 is surrounded by the second molding material 152. The optical engine 170 includes photonic integrated circuits (PIC) 171, electronic integrated circuits (EIC) 180, a connector 184, and a third molding material 185. The upper surface of the optical engine 170 may have the same level as the level of the upper surface of the semiconductor die 160 and the upper surface of the memory stacking structure 190.

The photonic integrated circuit (PIC) 171 is disposed on the interconnection structure 130, and is disposed at the lowermost portion of the optical engine 170. The photonic integrated circuit 171 includes second connection pads 172, second connection members 173, third lower connection pads 174, third through silicon vias 175, and third upper connection pads 176.

The photonic integrated circuit (PIC) 171 is configured to detect, receive, and process optical signals from optical fibers, to change the optical signals into current signals, and to transmit the current signals to the electronic integrated circuit (EIC) 180. In the embodiment, the photonic integrated circuit (PIC) 171 may include at least one of an optical waveguide, an optical modulator, a photo detector (PD), a grating coupler, and a laser diode.

The second connection pads 172 are disposed between the second connection members 173 and the third lower connection pads 174. The second connection pad 172 electrically connects the third lower connection pad 174 to the second connection member 173. The second connection members 173 are disposed between the first upper connection pads 133 of the interconnection structure 130 and the second connection pads 172. The second connection members 173 electrically connect the second connection pad 172 to the first upper connection pad 133 of the interconnection structure 130. In the embodiment, the second connection pad 172 may include or may be formed of at least one of copper, nickel, zinc, gold, silver, platinum, palladium, chromium, titanium, and an alloy thereof. In the embodiment, the second connection member 173 may be a micro bump. In the embodiment, the second connection member 173 may include or may be formed of at least one of tin, silver, lead, nickel, copper, and an alloy thereof.

The third lower connection pads 174 are disposed between the third through silicon vias 175 and the second connection pads 172. The third lower connection pads 174 electrically connect the third through silicon via 175 to the second connection pad 172.

The third through silicon vias 175 are disposed between the third lower connection pads 174 and the third upper connection pads 176. The third through silicon via 175 electrically connects the third upper connection pad 176 to the third lower connection pad 174. Some of the third through silicon vias 175 electrically connect the electronic integrated circuit (EIC) 180 to the semiconductor die 160 through the interconnection structure 130. Some of the third through silicon vias 175 electrically connect the electronic integrated circuit (EIC) 180 to the redistribution structure 120 through the interconnection structure 130.

The third upper connection pads 176 are disposed between the fourth connection members 182 and the third through silicon vias 175. The third upper connection pads 176 electrically connect the fourth connection members 182 to the third through silicon via 175.

In the embodiment, the third through silicon via 175 may include or may be formed of at least one of tungsten, aluminum, copper, and an alloy thereof. Each of the third lower connection pad 174 and the third upper connection pad 176 may include or may be formed of at least one of copper, aluminum, silver, tin, gold, nickel, lead, titanium, and an alloy thereof.

The electronic integrated circuit (EIC) 180 is disposed on the photonic integrated circuit (PIC) 171. The electronic integrated circuit (EIC) 180 includes fourth connection pads 181 and fourth connection members 182. The upper surface of the electronic integrated circuit (EIC) 180 has the same level as the upper surface of the semiconductor die 160 and the upper surface of the memory stacking structure 190.

The electronic integrated circuit (EIC) 180 is configured to receive and amplify the current signal transmitted from the photonic integrated circuit (PIC) 171, to change the current signal into a voltage signal, to transmit the voltage signal to the semiconductor die 160, and to receive a signal from the semiconductor die 160 and transmit the signal to the photonic integrated circuit (PIC) via a physical layer transceiver (PHY). In the embodiment, the electronic integrated circuit (EIC) 180 includes a control circuit for controlling an operation of the photonic integrated circuit (PIC) 171 according to signals received from the semiconductor die 160, and a circuit for processing a current signal from the photon integrated circuit (PIC) 171. In the embodiment, the electronic integrated circuit (EIC) 180 may include at least one of a central processing unit (CPU), a controller, and an amplifier.

The fourth connection pads 181 are disposed between the electronic integrated circuit base and the fourth connection members 182. The fourth connection pad 181 electrically connects the electronic integrated circuit base to the fourth connection member 182. The fourth connection members 182 are disposed between the fourth connection pads 181 and the third upper connection pads 176 of the photonic integrated circuit (PIC) 171. The fourth connection member 182 electrically connects the fourth connection pad 181 to the third upper connection pad 176 of the photonic integrated circuit (PIC) 171. In the embodiment, the fourth connection pad 181 may include or may be formed of at least one of copper, nickel, zinc, gold, silver, platinum, palladium, chromium, titanium, and an alloy thereof. In the embodiment, the fourth connection member 182 may be a micro bump. In the embodiment, the fourth connection member 182 may include or may be formed of at least one of tin, silver, lead, nickel, copper, and an alloy thereof.

The connector 184 is disposed on the photonic integrated circuit (PIC) 171. The connector 184 is connected to an optical fiber, and transmits an optical signal from the optical fiber to the photonic integrated circuit (PIC) 171. The upper surface of the connector 184 has the same level as the upper surface of the semiconductor die 160 and the upper surface of the memory stacking structure 190.

The third molding material 185 covers the electronic integrated circuit (EIC) 180 and the connector 184 on the photonic integrated circuit (PIC) 171. The third molding material 185 protects the electronic integrated circuit (EIC) 180 and the connector 184 from the external environment.

The second molding material 152 molds the semiconductor die 160, the optical engine 170, and the stacked core dies 192 on the first molding material 151. The second molding material 152 protects the semiconductor die 160, the optical engine 170, and the stacked core dies 192 from the external environment.

The present disclosure may have a structure in which the buffer die 191 of the memory stacked structure 190 is disposed on the redistribution structure 120 side by side the interconnection structure 130 and the semiconductor die 160 is disposed on the buffer die 191 and the interconnection structure 130. Accordingly, with this packaging structure, power loss occurring during signal transmission may be reduced to improve power efficiency, and the size of the semiconductor package may be reduced.

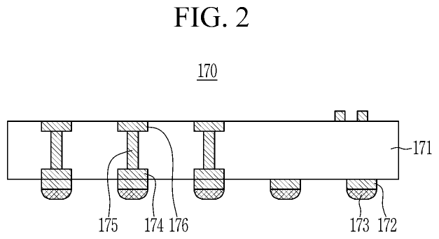

FIG. 2 to FIG. 5 illustrate cross-sectional views of a manufacturing method of the optical engine 170.

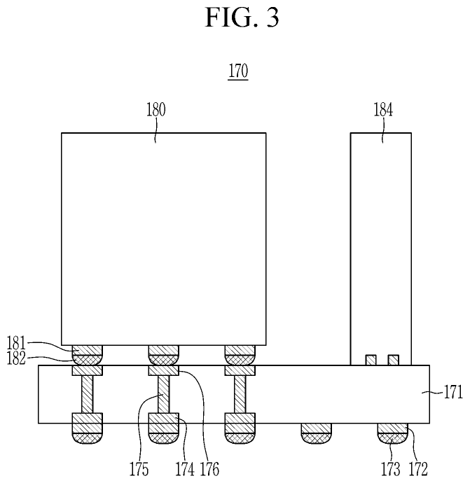

Referring to FIG. 2 and FIG. 3, the photonic integrated circuit (PIC) 171 is provided, and the electronic integrated circuit (EIC) 180 and the connector 184 are mounted on the photonic integrated circuit (PIC) 171. The electronic integrated circuit (EIC) 180 is disposed on the photonic integrated circuit (PIC) 171 by flip chip bonding. Each of the fourth connection members 182 of the electronic integrated circuit (EIC) 180 is disposed to be electrically connected to a corresponding one of the third through silicon vias 175.

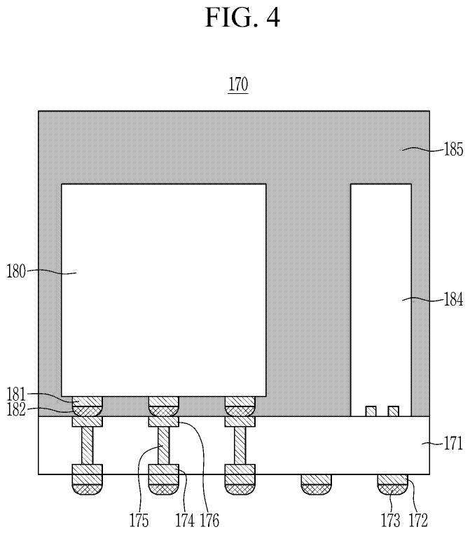

Referring to FIG. 4, the electronic integrated circuit (EIC) 180 and the connector 184 are covered with the third molding material 185 on the photonic integrated circuit (PIC) 171. In the embodiment, the process of molding with the third molding material 185 may include a compression molding or transfer molding process. In the example, the third molding material 185 may include or may be formed of an epoxy molding compound (EMC).

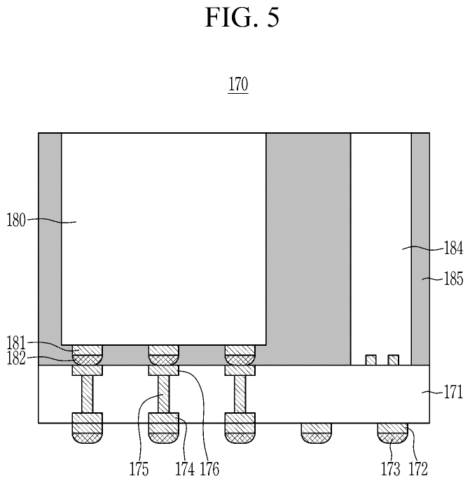

Referring to FIG. 5, chemical mechanical polishing (CMP) is performed to level the upper surface of the third molding material 185. The upper surface of the third molding material 185 is planarized by applying a CMP process. After performing the CMP process, the upper surface of the electronic integrated circuit (EIC) 180 and the upper surface of connector 184 are exposed.

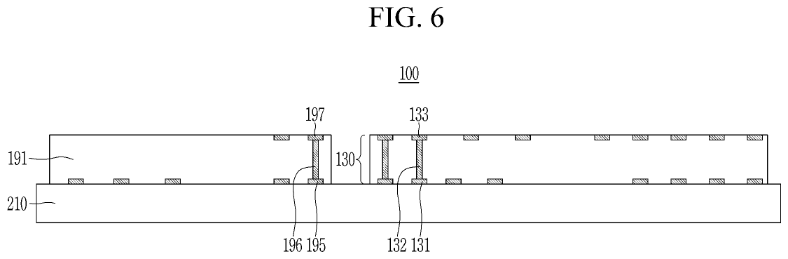

FIG. 6 to FIG. 15 illustrate cross-sectional views of a manufacturing method of the semiconductor package 100 of FIG. 1.

FIG. 6 illustrates a cross-sectional view of a step of attaching the interconnection structure 130 and the buffer die 191 on a carrier 210.

Referring to FIG. 6, the interconnection structure 130 and the buffer die 191 are attached on the carrier 210. In the embodiment, the carrier 210 may include or may be formed of a silicon-based material such as glass and a silicon oxide, an organic material, or another material such as an aluminum oxide, a combination of these materials, and the like. In the embodiment, the interconnection structure 130 and the buffer die 191 may be attached by a laser.

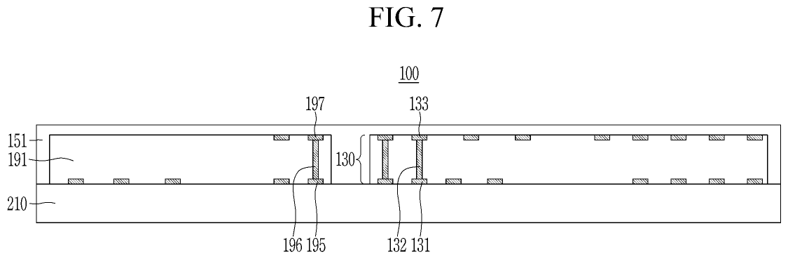

FIG. 7 illustrates a cross-sectional view of a step of molding the interconnection structure 130 and the buffer die 191 with the first molding material 151 on the carrier 210.

Referring to FIG. 7, the interconnection structure 130 and the buffer die 191 are covered with the first molding material 151 on the carrier 210. In the embodiment, the process of molding with the first molding material 151 may include a compression molding or transfer molding process. In the embodiment, the first molding material 151 may include or may be formed of an epoxy molding compound (EMC).

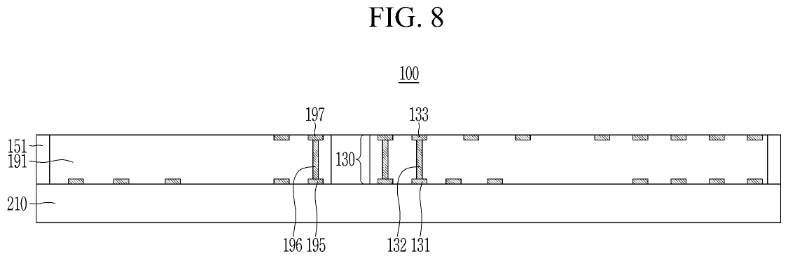

FIG. 8 illustrates a cross-sectional view of a step of planarizing the first molding material 151.

Referring to FIG. 8, chemical mechanical polishing (CMP) is performed to level the upper surface of the first molding material 151. The upper surface of the first molding material 151 is planarized by applying a CMP process. After performing the CMP process, the upper surface of the interconnection structure 130 and the upper surface of the buffer die 191 is exposed.

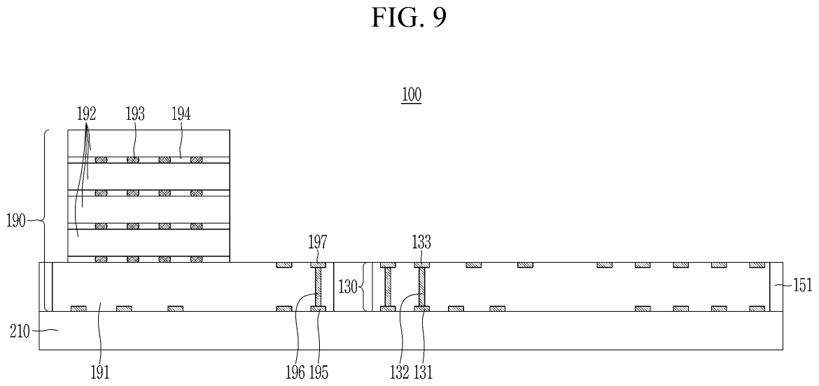

FIG. 9 illustrates a cross-sectional view of a step of stacking the core dies 192 on the buffer die 191.

Referring to FIG. 9, the core dies 192 are stacked on the buffer die 191. In the embodiment, the core dies 192 may be stacked by flip chip bonding. In the embodiment, the core dies 192 may be stacked by hybrid bonding.

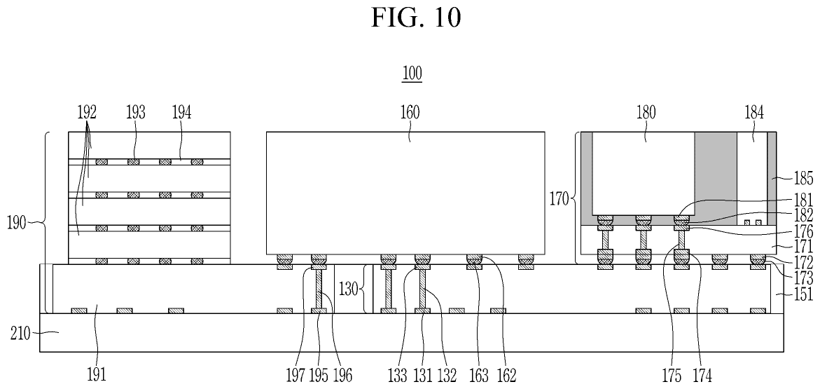

FIG. 10 illustrates a cross-sectional view of a step of mounting the semiconductor die 160 on the buffer die 191 and the interconnection structure 130 and mounting the optical engine 170 on the interconnection structure 130.

Referring to FIG. 10, the semiconductor die 160 is mounted on the buffer die 191 and the interconnection structure 130 by flip chip bonding. The optical engine 170 is mounted on the interconnection structure 130 by flip chip bonding.

The first connection members 163 of the semiconductor die 160 are bonded to the first upper connection pads 133 of the interconnection structure 130 and the second upper connection pads 197 of the buffer die 191, and the semiconductor die 160 is electrically connected to the interconnection structure 130 and the buffer die 191.

The second connection members 173 of the optical engine 170 are bonded to the first upper connection pads 133 of the interconnection structure 130, and the optical engine 170 is electrically connected to the interconnection structure 130.

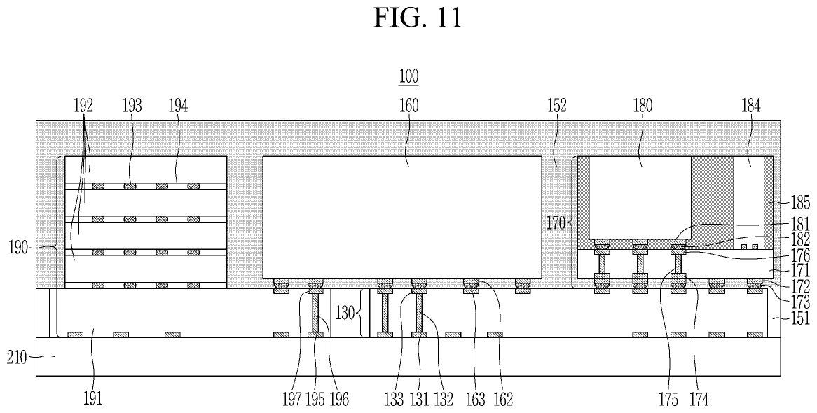

FIG. 11 illustrates a cross-sectional view of a step of molding the semiconductor die 160, the optical engine 170, and the stacked core dies 192 on the first molding material 151 with the second molding material 152.

Referring to FIG. 11, the semiconductor die 160, the optical engine 170, and the stacked core dies 192 are molded with the second molding material 152 on the first molding material 151. In the embodiment, the process of molding with the second molding material 152 may include a compression molding or transfer molding process. In the embodiment, the second molding material 152 may include or may be formed of an epoxy molding compound (EMC).

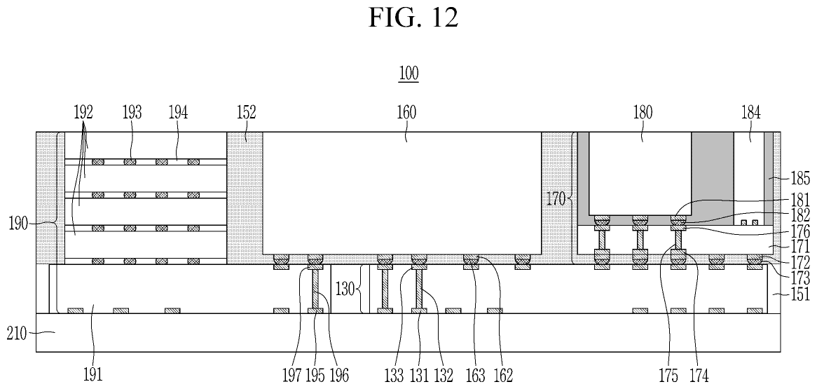

FIG. 12 illustrates a cross-sectional view of a step of planarizing the second molding material 152.

Referring to FIG. 12, chemical mechanical polishing (CMP) is performed to level the upper surface of the second molding material 152. The upper surface of the second molding material 152 is planarized by applying a CMP process. After performing the CMP process, the upper surface of the semiconductor die 160, the upper surface of the optical engine 170, and the upper surface of the memory stacking structures 190 is exposed. In this case, the levels of the upper surfaces of the second molding material 152, the semiconductor die 160, the optical engine 170, and the memory stacking structures 190 are all the same.

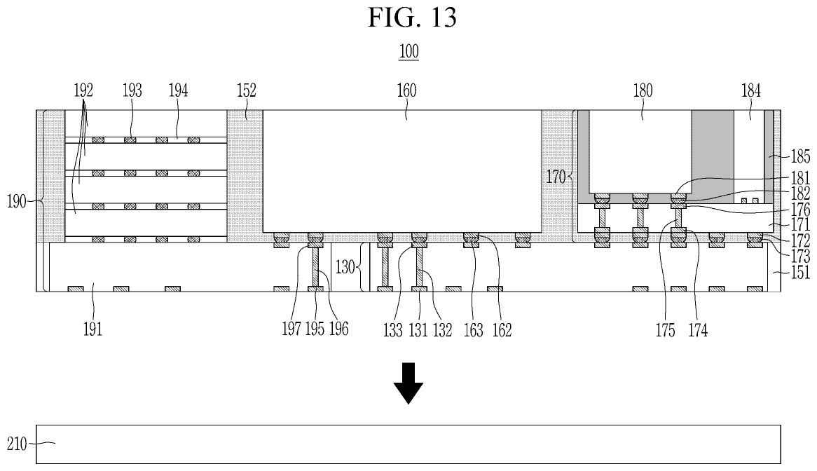

FIG. 13 illustrates a cross-sectional view of a step of removing the carrier 210 from the lower surface of the first molding material 151.

Referring to FIG. 13, the carrier 210 is removed from the lower surface of the first molding material 151 to expose the lower surface of the first molding material 151.

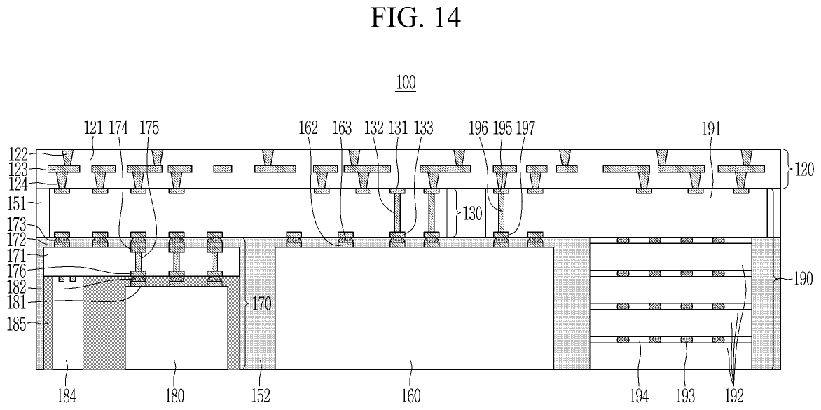

FIG. 14 illustrates a cross-sectional view of a step of forming a redistribution structure 120 on the interconnection structure 130, the buffer die 191, and the first molding material 151.

Referring to FIG. 14, an intermediate product of the semiconductor package 100 is disposed upside down, and the redistribution structure 120 is formed on the interconnection structure 130, the buffer die 191, and the first molding material 151. According to the present disclosure, since the dielectric layer 121 is formed directly on the interconnect structure 130, the buffer die 191, and the first molding material 151, connection members such as micro bumps and solder bumps are not used between the redistribution structure 120 and each of the interconnection structure 130, the buffer die 191, and the first molding material 151.

The dielectric layer 121 is formed on the interconnection structure 130, the buffer die 191, and the first molding material 151. In the embodiment, the dielectric layer 121 may include or may be formed of a photoimageable dielectric (PID) used in a redistribution process. The photoimageable dielectric (PID) is a material in which fine patterns may be formed by applying a photolithography process. As an example, the PID may include a polyimide-based photosensitive polymer, a novolak-based photosensitive polymer, polybenzoxazole, a silicon-based polymer, an acrylate-based polymer, or an epoxy-based polymer. In the embodiment, the dielectric layer 121 is made of an inorganic dielectric material such as silicon nitride, silicon oxide, and the like. In the embodiment, the dielectric layer 121 may be formed by a chemical vapor deposition (CVD), atomic layer deposition (ALD), or plasma enhanced CVD (PECVD) process.

After forming the dielectric layer 121, the dielectric layer 121 is selectively etched to form the via holes, and the via holes are filled with a conductive material to form the second redistribution vias 124. Since the second redistribution vias 124 are formed after the intermediate product of the semiconductor package 100 is disposed upside down, the uppermost width of the second redistribution vias 124 is larger than the lowermost width thereof. In the final product, the uppermost width of the second redistribution vias 124 is smaller than the lowermost width thereof.

Next, the dielectric layer 121 is additionally deposited on the second redistribution vias 124 and the dielectric layer 121, the additionally deposited dielectric layer 121 is selectively etched to form openings, and the openings are filled with a conductive material to form the first redistribution lines 123.

Next, the dielectric layer 121 is additionally deposited on the first redistribution lines 123 and the dielectric layer 121, the additionally deposited dielectric layer 121 is selectively etched to form via holes, and the via holes are filled with a conductive material to form the first redistribution vias 122. For the same reason as the second redistribution vias 124, in the final product, the uppermost width of the first redistribution vias 122 is smaller than the lowermost width thereof. For example, the dielectric layer 121 in the final product may be formed by depositing a dielectric material layer multiple times (e.g., three times).

In the embodiment, the first redistribution vias 122, the first redistribution lines 123, and the second redistribution vias 124 may include or may be formed of at least one of copper, aluminum, tungsten, nickel, gold, tin, titanium, an alloy thereof, and the like. In the embodiment, the first redistribution vias 122, the first redistribution lines 123, and the second redistribution vias 124 may be formed by performing an electroplating process after forming a seed metal layer. In the embodiment, the first redistribution vias 122, the first redistribution lines 123, and the second redistribution vias 124 may be formed by performing a sputtering process.

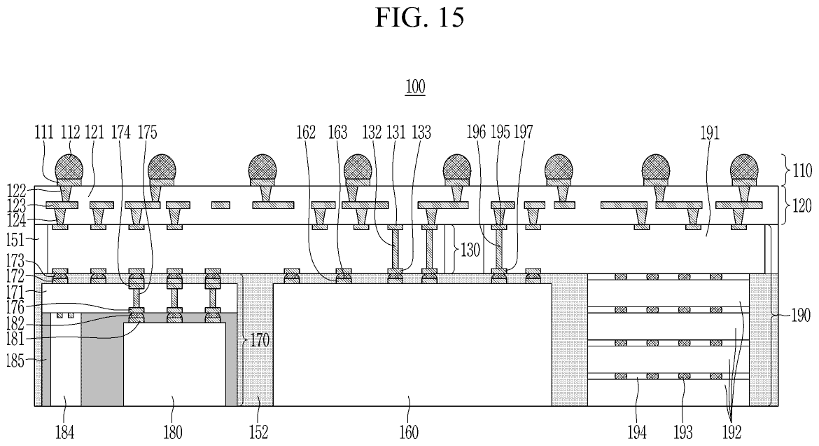

FIG. 15 illustrates a cross-sectional view of a step of forming the external connection structure 110 on the lower surface of the redistribution structure 120.

Referring to FIG. 15, the external connection structure 110 is formed on the lower surface of the redistribution structure 120. The conductive pads 111 are formed under the first redistribution vias 122 of the redistribution structure 120, and the external connection members 112 are formed under the conductive pads 111. In the embodiment, the conductive pad 111 may include or may be formed of at least one of copper, nickel, zinc, gold, silver, platinum, palladium, chromium, titanium, and an alloy thereof. In the embodiment, the external connection member 112 may include or may be formed of at least one of tin, silver, lead, nickel, copper, and an alloy thereof. In the embodiment, the conductive pad 111 may be formed by performing a sputtering process, or by performing an electroplating process after forming a seed metal layer.

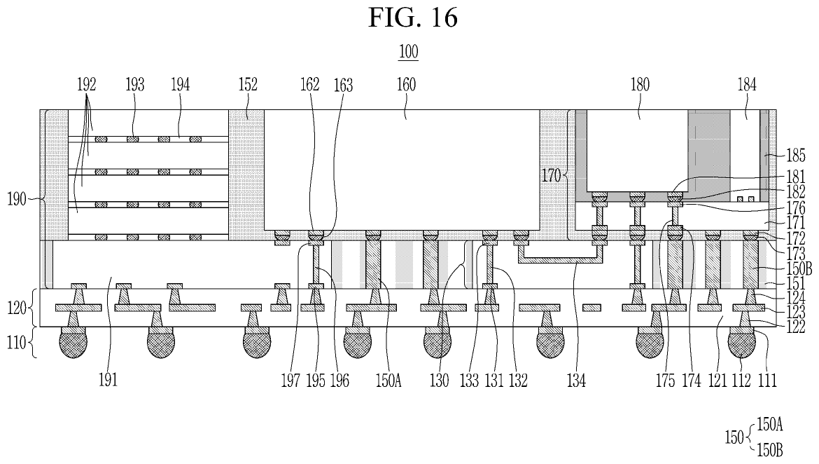

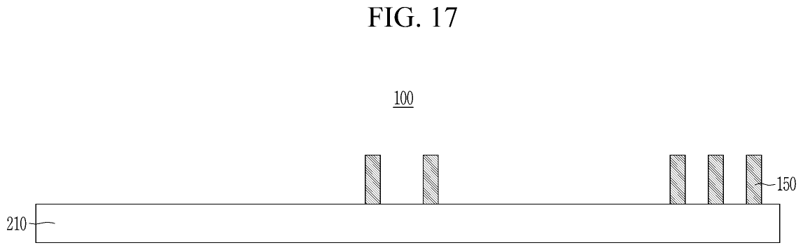

FIG. 16 illustrates a cross-sectional view of a semiconductor package 100 according to an embodiment. FIG. 16 illustrates a cross-sectional view of a semiconductor package 100 manufactured using a manufacturing method of FIG. 17 to FIG. 27.

Referring to FIG. 16, the semiconductor package 100 includes an external connection structure 110, a redistribution structure 120, an interconnection structure 130, conductive posts (third connection members) 150, a first molding material 151, a semiconductor die 160, an optical engine 170, memory stacking structures 190, and a second molding material 152.

The interconnection structure 130 electrically connects the semiconductor die 160 to the optical engine 170 in the horizontal direction, electrically connects the optical engine 170 to the redistribution structure 120 in the vertical direction, and electrically connects the semiconductor die 160 to the redistribution structure 120 in the vertical direction.

The interconnection structure 130 includes first lower connection pads 131, first through silicon vias (TSV) 132, first upper connection pads 133, and a first upper connection line 134. In the embodiment, the interconnection structure 130 may include a bridge die. In the embodiment, the interconnection structure 130 may include a silicon bridge. The side surface of the interconnection structure 130 is covered with the first molding material 151. The first through silicon via (TSV) 132 included in the first bridge die quickly moves data in the vertical direction, and the first upper connection line 134 quickly moves data in the horizontal direction. For example, the first through-hole silicon via (TSV) 132 included in the first bridge die may serve as a shorter vertical signal path for transferring data in the vertical direction, and the first upper connection lines 134 may serve as a shorter horizontal signal path for transferring data in the horizontal direction. Accordingly, the signal transmission path between the semiconductor die 160 and the optical engine 170, and the semiconductor die 160 and the redistribution structure 120 may be optimized (i.e., reduced), thereby reducing power consumption to improve the performance of the semiconductor package.

The first lower connection pad 131 is disposed between the second redistribution via 124 of the redistribution structure 120 and the first through silicon via (TSV) 132, and electrically connects the first through silicon via (TSV) 132 to the second redistribution via 124 of the redistribution structure 120.

The first through silicon via (TSV) 132 is disposed between the first lower connection pad 131 and the first upper connection pad 133, and electrically connects the semiconductor die 160 connected to the first upper connection pad 133 in the vertical direction to the redistribution structure 120 connected to the first lower connection pad 131.

The first upper connection pad 133 is disposed between the first through silicon via (TSV) 132 and the first connection member 163 and between the first through silicon via (TSV) 132 and the second connection member 173. The first upper connection pad 133 electrically connects the first connection member 163 and the second connection member 173 to the first through silicon via (TSV) 132, and electrically connect the first connection member 163 and the second connection member 173 to the first upper connection line 134.

The first upper connection line 134 is disposed between the first upper connection pads 133, and electrically connects the semiconductor die 160 connected to the first upper connection pad 133 to the optical engine 170 connected to the first upper connection pad 133 in the horizontal direction.

In the embodiment, the first through silicon via (TSV) 132 may include or may be formed of at least one of tungsten, aluminum, copper, and an alloy thereof. In the embodiment, each of the first lower connection pad 131 and the first upper connection pad 133 may include or may be formed of at least one of copper, aluminum, silver, tin, gold, nickel, lead, titanium, and an alloy thereof. In the embodiment, the first upper connection line 134 may include at least one of copper, aluminum, silver, tin, gold, nickel, lead, titanium, tungsten, and an alloy thereof.

The conductive posts 150 are disposed on the upper surface of the redistribution structure 120. The conductive posts 150 include first conductive posts 150A that are disposed under the semiconductor die 160. The first conductive posts 150A are disposed around the interconnection structure 130 and between the interconnection structure 130 and the buffer die 191. The conductive posts 150 further include second conductive posts 150B that are disposed below the optical engine 170.

The conductive post 150 electrically connects the first connection member 163 and the second connection member 173 to the second redistribution via 124 of the redistribution structure 120. For example, the first conductive posts 150A electrically connect the first connection members 163 to the second redistribution vias 124, and the second conductive posts 150B electrically connect the second connection members 173 to the the second redistribution vias 124. The conductive post 150 is disposed through the first molding material 151. The side surface of the conductive post 150 is surrounded by the first molding material 151.

The contents described with respect to FIG. 1 are equally applied to configurations other than those described with respect to FIG. 16.

FIG. 17 to FIG. 27 illustrate cross-sectional views of a manufacturing method of the semiconductor package 100 of FIG. 16.

FIG. 17 illustrates a cross-sectional view of a step of forming the conductive posts 150 on the carrier 210.

Referring to FIG. 17, the conductive posts 150 are formed on the carrier 210. In the embodiment, the carrier 210 may include or may be formed of a silicon-based material such as glass and silicon oxide, an organic material, or another material such as an aluminum oxide, a combination of these materials, and the like.

The conductive posts 150 are formed on the carrier 210 in the vertical direction. In the embodiment, the conductive posts 150 may be formed by performing an electrolytic plating process after forming a seed metal layer. In the embodiment, the conductive posts 150 may be formed by performing a sputtering process. In the embodiment, the conductive post 150 may include or may be formed of at least one of copper, aluminum, tungsten, nickel, gold, silver, chromium, antimony, tin, titanium, and an alloy thereof.

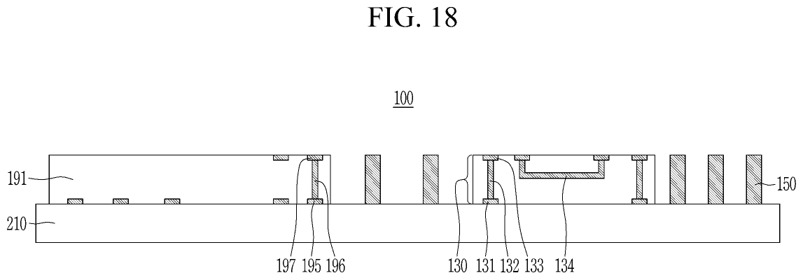

FIG. 18 illustrates a cross-sectional view of a step of attaching the interconnection structure 130 and the buffer die 191 on a carrier 210.

Referring to FIG. 18, the interconnection structure 130 and the buffer die 191 are attached on the carrier 210. In the embodiment, the interconnection structure 130 and the buffer die 191 may be attached by a laser.

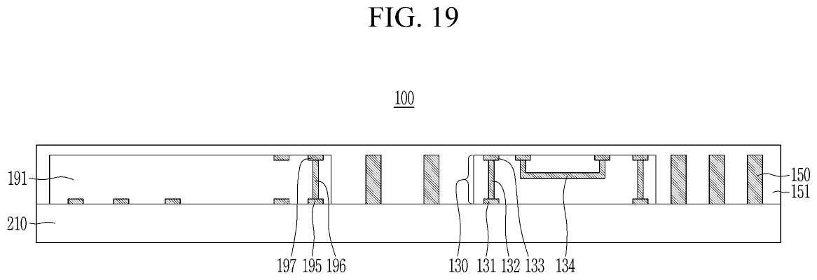

FIG. 19 illustrates a cross-sectional view of a step of molding the interconnection structure 130 and the buffer die 191 with the first molding material 151 on the carrier 210.

Referring to FIG. 19, the interconnection structure 130 and the buffer die 191 are molded with the first molding material 151 on the carrier 210. In the embodiment, the process of molding with the first molding material 151 may include a compression molding or transfer molding process. In the embodiment, the first molding material 151 may include or may be formed of an epoxy molding compound (EMC).

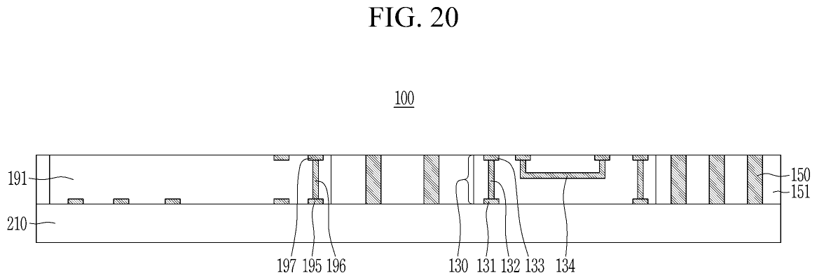

FIG. 20 illustrates a cross-sectional view of a step of planarizing the first molding material 151.

Referring to FIG. 20, chemical mechanical polishing (CMP) is performed to level the upper surface of the first molding material 151. The upper surface of the first molding material 151 is planarized by applying a CMP process. After performing the CMP process, the upper surface of the conductive posts 150, the upper surface of the interconnection structure 130 and the upper surface of the buffer die 191 are exposed.

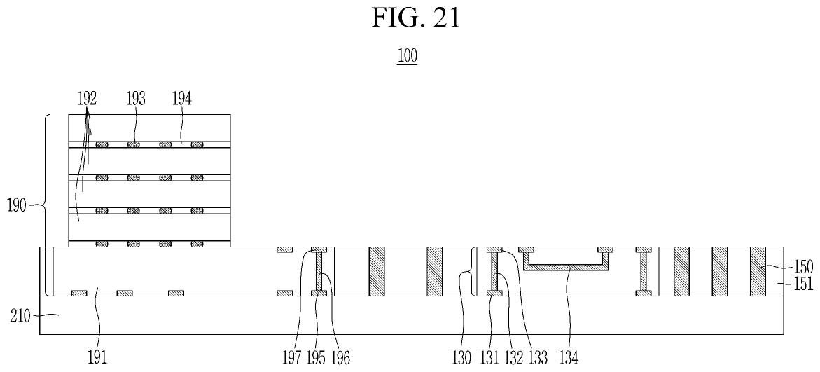

FIG. 21 illustrates a cross-sectional view of a step of stacking the core dies 192 on the buffer die 191.

Referring to FIG. 21, the core dies 192 are stacked on the buffer die 191. In the embodiment, the core dies 192 may be stacked by flip chip bonding. In the embodiment, the core dies 192 may be stacked by hybrid bonding.

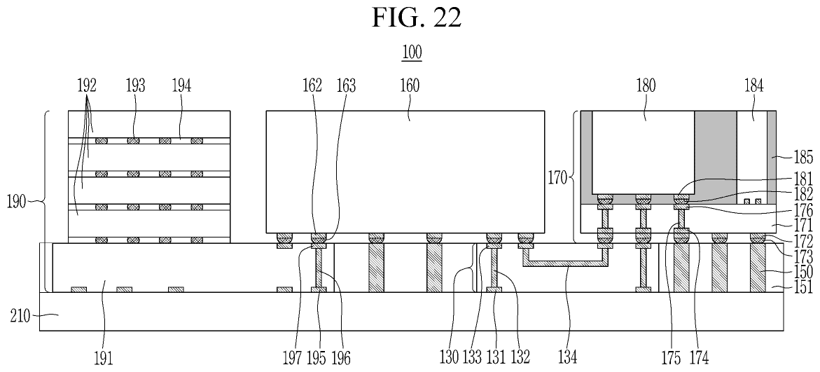

FIG. 22 illustrates a cross-sectional view of a step of mounting the semiconductor die 160 on the buffer die 191 and the interconnection structure 130 and mounting the optical engine 170 on the interconnection structure 130.

Referring to FIG. 22, the semiconductor die 160 is mounted on the buffer die 191 and the interconnection structure 130 by flip chip bonding. The optical engine 170 is mounted on the interconnection structure 130 by flip chip bonding.

The first connection members 163 of the semiconductor die 160 are bonded to the first upper connection pads 133 of the interconnection structure 130, the second upper connection pads 197 of the buffer die 191, and the conductive posts 150, and the semiconductor die 160 is electrically connected to the interconnection structure 130, the buffer die 191, and the conductive posts 150.

The second connection members 173 of the optical engine 170 are bonded to the first upper connection pads 133 of the interconnection structure 130 and the conductive posts 150, and the optical engine 170 is electrically connected to the interconnection structure 130 and the conductive posts 150.

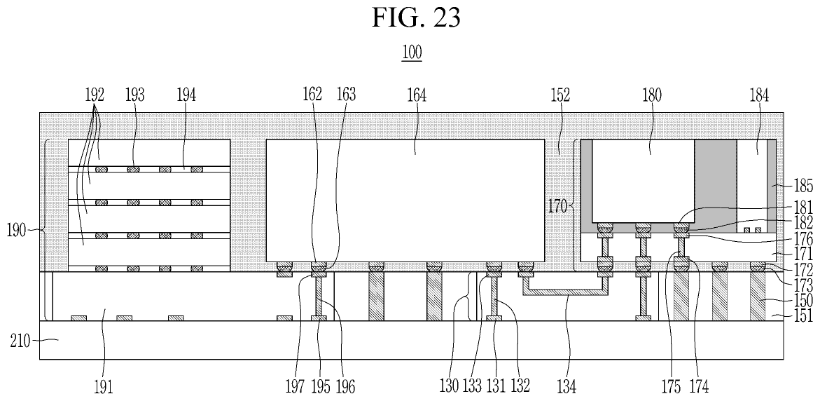

FIG. 23 illustrates a cross-sectional view of a step of molding the semiconductor die 160, the optical engine 170, and the stacked core dies 192 on the first molding material 151 with the second molding material 152.

Referring to FIG. 23, the semiconductor die 160, the optical engine 170, and the stacked core dies 192 are molded with the second molding material 152 on the first molding material 151. In the embodiment, the process of molding with the second molding material 152 may include a compression molding or transfer molding process. In the embodiment, the second molding material 152 may include or may be formed of an epoxy molding compound (EMC).

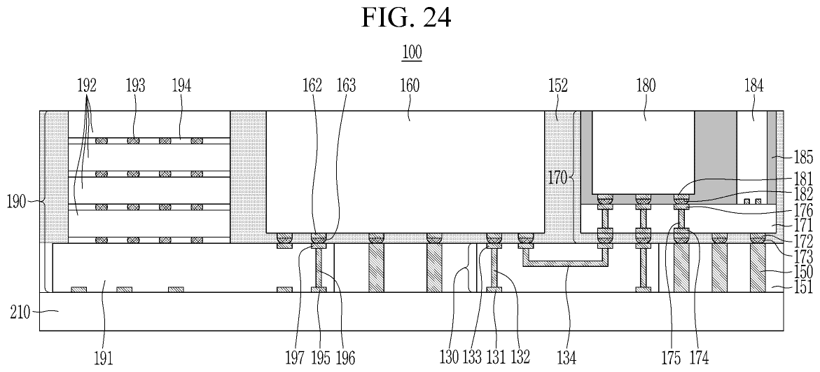

FIG. 24 illustrates a cross-sectional view of a step of planarizing the second molding material 152.

Referring to FIG. 24, chemical mechanical polishing (CMP) is performed to level the upper surface of the second molding material 152. The upper surface of the second molding material 152 is planarized by applying a CMP process. After performing the CMP process, the upper surface of the semiconductor die 160, the upper surface of the optical engine 170, and the upper surface of the memory stacking structures 190 are exposed. In this case, the levels of the upper surface of the second molding material 152, the upper surface of the semiconductor die 160, the upper surface of the optical engine 170, and the upper surface of the memory stacking structures 190 are all the same.

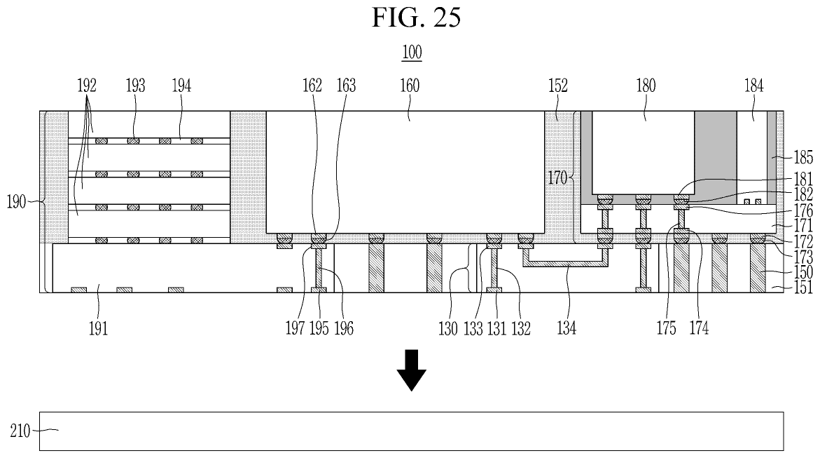

FIG. 25 illustrates a cross-sectional view of a step of removing the carrier 210 from the lower surface of the first molding material 151.

Referring to FIG. 25, the carrier 210 is removed from the lower surface of the first molding material 151.

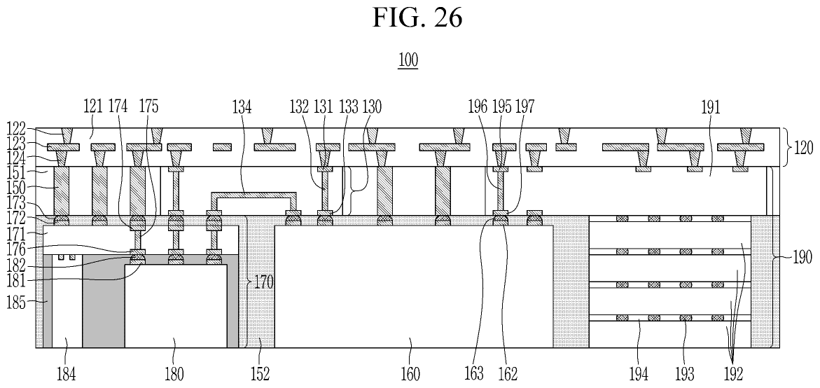

FIG. 26 illustrates a cross-sectional view of a step of forming the redistribution structure 120 on the interconnection structure 130, the buffer die 191, the conductive posts 150, and the first molding material 151.

Referring to FIG. 26, an intermediate product of the semiconductor package 100 is disposed upside down, and the redistribution structure 120 is formed on the interconnection structure 130, the buffer die 191, the conductive posts 150, and the first molding material 151. According to the present disclosure, since the dielectric layer 121 is formed directly on the interconnect structure 130, the buffer die 191, the conductive posts 150, and the first molding material 151, connection members such as micro bumps and solder bumps are not used between the redistribution structure 120 and each of the interconnection structure 130, the buffer die 191, the conductive posts 150, and the first molding material 151.

The dielectric layer 121 is formed on the interconnection structure 130, the buffer die 191, the conductive posts 150, and the first molding material 151. In the embodiment, the dielectric layer 121 may include or may be formed of a photoimageable dielectric (PID) used in a redistribution process. The photoimageable dielectric (PID) is a material in which fine patterns may be formed by applying a photolithography process. As an example, the PID may include a polyimide-based photosensitive polymer, a novolak-based photosensitive polymer, polybenzoxazole, a silicon-based polymer, an acrylate-based polymer, or an epoxy-based polymer. In the embodiment, the dielectric layer 121 is made of an inorganic dielectric material such as silicon nitride, silicon oxide, and the like. In the embodiment, the dielectric layer 121 may be formed by a CVD, ALD, or PECVD process.

After forming the dielectric layer 121, the dielectric layer 121 is selectively etched to form the via holes, and the via holes are filled with a conductive material to form the second redistribution vias 124. Since the second redistribution vias 124 are formed after the intermediate product of the semiconductor package 100 is disposed upside down, the uppermost width of the second redistribution vias 124 is larger than the lowermost width thereof. In the final product, the uppermost width of the second redistribution vias 124 is smaller than the lowermost width thereof.

Next, the dielectric layer 121 is additionally deposited on the second redistribution vias 124 and the dielectric layer 121, the additionally deposited dielectric layer 121 is selectively etched to form openings, and the openings are filled with a conductive material to form the first redistribution lines 123.

Next, the dielectric layer 121 is additionally deposited on the first redistribution lines 123 and the dielectric layer 121, the additionally deposited dielectric layer 121 is selectively etched to form via holes, and the via holes are filled with a conductive material to form the first redistribution vias 122. For the same reason as the second redistribution vias 124, in the final product, the uppermost width of the first redistribution vias 122 is smaller than the lowermost width thereof. For example, the dielectric layer 121 in the final product may be formed by depositing a dielectric material layer multiple times (e.g., three times).

In the embodiment, the first redistribution vias 122, the first redistribution lines 123, and the second redistribution vias 124 may include or may be formed of at least one of copper, aluminum, tungsten, nickel, gold, tin, titanium, an alloy thereof, and the like. In the embodiment, the first redistribution vias 122, the first redistribution lines 123, and the second redistribution vias 124 may be formed by performing an electroplating process after forming a seed metal layer. In the embodiment, the first redistribution vias 122, the first redistribution lines 123, and the second redistribution vias 124 may be formed by performing a sputtering process.

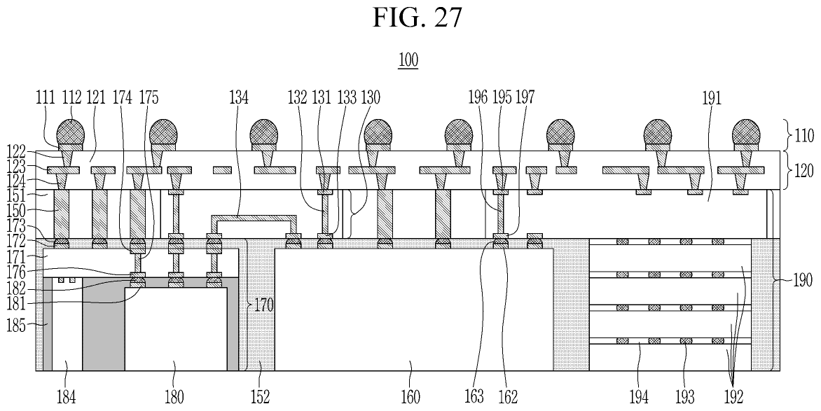

FIG. 27 illustrates a cross-sectional view of a step of forming the external connection structure 110 on the lower surface of the redistribution structure 120.

Referring to FIG. 27, the external connection structure 110 is formed on the lower surface of the redistribution structure 120. The conductive pads 111 are formed under the first redistribution vias 122 of the redistribution structure 120, and the external connection members 112 are formed under the conductive pads 111. In the embodiment, the conductive pad 111 may include or may be formed of at least one of copper, nickel, zinc, gold, silver, platinum, palladium, chromium, titanium, and an alloy thereof. In the embodiment, the external connection member 112 may include at least one of tin, silver, lead, nickel, copper, and an alloy thereof. In the embodiment, the conductive pad 111 may be formed by performing a sputtering process, or by performing an electroplating process after forming a seed metal layer.

While this disclosure has been described in connection with what is presently considered to be practical embodiments, it is to be understood that the disclosure is not limited to the disclosed embodiments, but, on the contrary, is intended to cover various modifications and equivalent arrangements included within the spirit and scope of the appended claims.

What is claimed is:

1. A semiconductor package comprising:
a redistribution structure;
an interconnection structure on the redistribution structure;
a memory stacking structure disposed on the redistribution structure, and including a buffer die and core dies stacked on the buffer die;
a semiconductor die disposed on the buffer die and on the interconnection structure; and
an optical engine disposed on the interconnection structure.

2. The semiconductor package of claim 1,
wherein an upper surface of the buffer die and an upper surface of the interconnect structure are at the same level.

3. The semiconductor package of claim 1,
wherein an upper surface of the memory stacking structure, an upper surface of the semiconductor die, and an upper surface of the optical engine are at the same level.

4. The semiconductor package of claim 1, wherein:
the interconnection structure includes a plurality of first through silicon vias connecting the semiconductor die to the redistribution structure, and
the buffer die includes a plurality of second through silicon vias connecting the semiconductor die to the redistribution structure.

5. The semiconductor package of claim 1,
wherein the interconnection structure electrically connects the semiconductor die to the optical engine.

6. The semiconductor package of claim 1, wherein:
the semiconductor die includes a plurality of first connection members,
some of the plurality of first connection members are directly connected to the buffer die, and
others of the plurality of first connection members are directly connected to the interconnection structure.

7. The semiconductor package of claim 6,
wherein the plurality of first connection members are micro bumps.

8. The semiconductor package of claim 1,
wherein the interconnection structure is a silicon interposer.

9. The semiconductor package of claim 1,
wherein the interconnection structure is a bridge die.

10. The semiconductor package of claim 9,
wherein the bridge die is a silicon bridge.

11. The semiconductor package of claim 9, further comprising:
a plurality of first conductive posts disposed between the bridge die and the buffer die and electrically connecting the semiconductor die to the redistribution structure.

12. The semiconductor package of claim 11, further comprising:
a plurality of second conductive posts below the optical engine and electrically connecting the optical engine to the redistribution structure.

13. A semiconductor package comprising:
a redistribution structure;
an interconnection structure on the redistribution structure;
a memory stacking structure disposed on the redistribution structure and including a buffer die and core dies stacked on the buffer die;
a first molding material disposed on the redistribution structure and covering the interconnection structure and the buffer die;
a semiconductor die disposed on the buffer die and on the interconnection structure;
an optical engine disposed on the interconnection structure; and
a second molding material disposed on the first molding material and covering the stacked core dies, the semiconductor die, and the optical engine.

14. The semiconductor package of claim 13,
wherein the semiconductor die includes an XPU.

15. The semiconductor package of claim 13,
wherein the optical engine includes a photonic integrated circuit (PIC) and an electronic integrated circuit (EIC) on the photonic integrated circuit (PIC).

16. The semiconductor package of claim 15,
wherein the photonic integrated circuit (PIC) includes at least one of an optical waveguide, an optical modulator, a photo detector (PD), a grating coupler, and a laser diode.

17. The semiconductor package of claim 15, wherein:
the photonic integrated circuit (PIC) includes a plurality of through silicon vias, and
the plurality of through silicon vias electrically connect the electronic integrated circuit (EIC) to the interconnection structure.

18. The semiconductor package of claim 15, wherein:
the optical engine further includes a connector, and
the connector is connected to an external optical fiber.

19. A manufacturing method of a semiconductor package, comprising:
attaching a buffer die and an interconnection structure onto a carrier;
molding the buffer die and the interconnection structure on the carrier with a first molding material;
forming core dies stacked on the buffer die, mounting a semiconductor die on the buffer die and the interconnection structure, and mounting an optical engine on the interconnection structure;
molding the stacked core dies, the semiconductor die, and the optical engine on the first molding material with a second molding material;
removing the carrier to expose the buffer die and the interconnect structure; and
forming a redistribution structure on the buffer die and the interconnect structure.

20. The manufacturing method of the semiconductor package of claim 19, further comprising:
after the molding of the stacked core dies, the semiconductor die, and the optical engine on the first molding material with the second molding material, performing a chemical mechanical polishing (CMP) process on the second molding material.
